(19) United States
(12) Patent Application Publication
(10) Pub. No.: US 2025/0370063 A1
(43) Pub. Date: Dec. 4, 2025

(54) ABNORMALITY DETECTION DEVICE, ONBOARD CHARGER, AND ABNORMALITY DETECTION METHOD

(71) Applicant: Panasonic Automotive Systems Co., Ltd., Kanagawa (JP)

(72) Inventor: Yohei NAGATAKE, Kanagawa (JP)

(21) Appl. No.: 19/084,310

(22) Filed: Mar. 19, 2025

(30) Foreign Application Priority Data
May 28, 2024 (JP) 2024-086325

(51) Int. Cl. G01R 31/42; B60L 1/00; B60L 53/22; B60L 53/62; G01R 15/14; G01R 31/52; G01R 35/00; H02J 7/00; H02J 7/04

(52) U.S. Cl. CPC G01R 31/42; B60L 1/006; B60L 53/22; B60L 53/62; G01R 15/146; G01R 31/52; G01R 35/00; H02J 7/0068; H02J 7/04; B60L 2210/30; B60L 2210/40

(57) ABSTRACT

An abnormality detection device according to the present disclosure includes a sensor and a control circuit. The sensor is electrically connected to a power supply line to which power from an external power supply when charging an onboard battery and power from the onboard battery when discharging to an external load are bidirectionally supplied. The sensor is configured to have an output offset such that a sensor value of an applied offset voltage is output in a state where charge/discharge power is not supplied to the power supply line and output the sensor value corresponding to a current or a voltage of the charge/discharge power. The control circuit is configured to detect an abnormality of the sensor in a case where the sensor value in a state where the charge/discharge power is not supplied to the power supply line is different from the offset voltage.

### CROSS-REFERENCE TO RELATED APPLICATIONS

This application is based upon and claims the benefit of priority from Japanese Patent Application No. 2024-086325, filed May 28, 2024, the entire contents of which are incorporated herein by reference.

### FIELD

The present disclosure relates to an abnormality detection device, an onboard charger, and an abnormality detection method.

### BACKGROUND

In an onboard charger, it is necessary to keep input and output current values constant by performing constant current control such that the current values become equivalent to request currents requested from a vehicle while monitoring detected values (sensor values) of a current sensor for an input current and an output current. Under such a circumstance, when an abnormality occurs in the current sensor, there is a risk that a power supply device connected to an input side, an onboard battery connected to an output side, and an onboard component are destroyed when, for example, the monitored sensor values become inaccurate and the input and output current values exceed the request currents. Therefore, in the onboard charger, it is necessary to constantly monitor whether or not the current sensor is normally operating.

For example, JP 2007-099033 A discloses a technique in which a current sensor that detects charge/discharge currents is provided in each of a plurality of batteries, and an abnormality of the current sensor is detected by comparing detected values of the current sensor.

However, in a configuration in which another sensor is added as a redundant sensor in order to monitor a sensor abnormality, there is a problem that costs increase or a component mounting area increases due to the addition. Therefore, there is a demand for a technique for detecting a sensor abnormality without adding a redundant sensor.

One of the problems to be solved by the present disclosure is to detect a sensor abnormality without adding a redundant sensor.

### SUMMARY

An abnormality detection device according to the present disclosure includes a sensor and a control circuit. The sensor is electrically connected to a power supply line to which power from an external power supply when charging an onboard battery and power from the onboard battery when discharging to an external load are bidirectionally supplied. The sensor is configured to have an output offset such that a sensor value of an applied offset voltage is output in a state where charge/discharge power is not supplied to the power supply line and output the sensor value corresponding to a current or a voltage of the charge/discharge power supplied to the power supply line. The control circuit is configured to detect an abnormality of the sensor in a case where the sensor value in a state where the charge/discharge power is not supplied to the power supply line is different from the offset voltage.

### BRIEF DESCRIPTION OF THE DRAWINGS

FIG. 1 is a diagram illustrating an example of a configuration of a charging system according to an embodiment;

FIG. 2 is a diagram illustrating an example of a configuration of a current sensor of FIG. 1;

FIG. 3 is a diagram for describing detection of a sensor abnormality based on an operation range related to the current sensor of FIG. 1;

FIG. 4 is a diagram illustrating an example of a configuration of a voltage sensor of FIG. 1;

FIG. 5 is a diagram for describing detection of a sensor abnormality based on an operation range related to the voltage sensor of FIG. 1;

FIG. 6 is a flowchart illustrating an example of a flow of processing of detecting a power supply fault abnormality or a ground fault abnormality (sensor abnormality) of the current sensor executed by a control circuit of FIG. 1;

FIG. 7 is a flowchart illustrating an example of a flow of processing of detecting a power supply fault abnormality or a ground fault abnormality (sensor abnormality) of the voltage sensor executed by the control circuit of FIG. 1;

FIG. 8 is a diagram illustrating an example of the configuration of each of the current sensor and the voltage sensor in FIG. 1; and

FIG. 9 is a flowchart illustrating an example of a flow of processing of detecting a gain error (sensor abnormality) of the current sensor or the voltage sensor executed by the control circuit of FIG. 1.

### DETAILED DESCRIPTION

Hereinafter, embodiments of a self-diagnosis circuit, an abnormality detection device, a power conversion device (onboard charger), a vehicle, a charging system, an abnormality detection method, a program, and a recording medium according to the present disclosure will be described with reference to the drawings.

In the description of the present disclosure, constituent elements having the same or substantially the same functions as those described above with reference to the previously described drawings are denoted by the same reference numerals, and the description thereof may be appropriately omitted. In addition, even in the case of representing the same or substantially the same portion, the dimensions and ratios may be expressed differently from each other depending on the drawings. Furthermore, for example, in order to ensure visibility of the drawings, in the description of each drawing, only main constituent elements are denoted by reference numerals, and even constituent elements having the same or substantially the same functions as those described above in the previous drawings may not be denoted by reference numerals.

In the description of the present disclosure, constituent elements having the same or substantially the same function may be distinguishably described by adding alphanumeric characters to the end of reference numerals. Alternatively, in a case where a plurality of constituent elements having the same or substantially the same function are not distinguished, the constituent elements may be collectively described by omitting alphanumeric characters added to the end of the reference numerals.

### First Embodiment

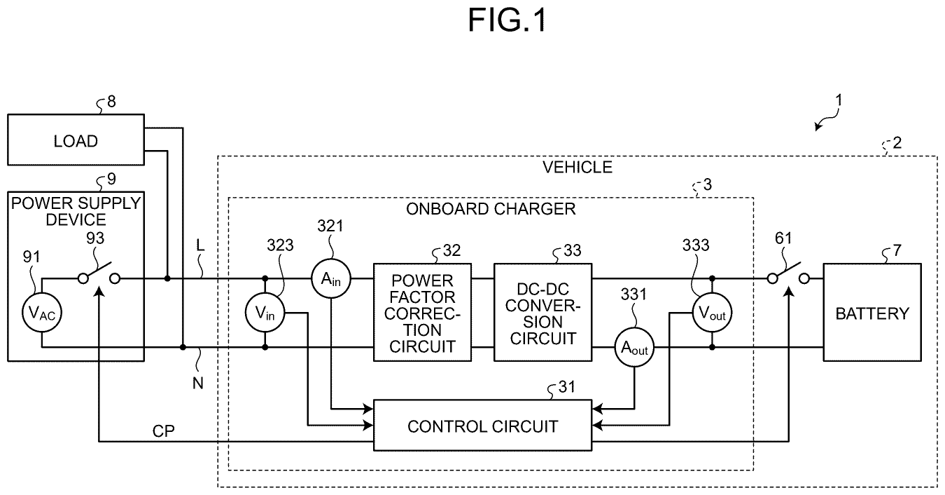

FIG. 1 is a diagram illustrating an example of a configuration of a charging system 1 according to an embodiment. As illustrated in FIG. 1, the charging system 1 includes a vehicle 2, a load 8, and a power supply device 9. The vehicle 2 further includes an onboard charger 3 and a battery 7.

In the vehicle 2, the onboard charger 3 is electrically connected to the battery 7 via a plurality of power supply lines L and N. For example, a switch 61 may be provided on the power supply line L between the onboard charger 3 and the battery 7. The switch 61 operates, for example, according to a control signal from a control circuit 31, and switches between conduction/disconnection between the onboard charger 3 and the battery 7. The switch 61 is not limited to operating according to the control signal from the control circuit 31 and may operate according to a control signal from a control circuit mounted outside the onboard charger 3 in the vehicle 2, such as an arbitrary onboard electronic control unit (ECU). Alternatively, the switch 61 may operate, for example, according to a control signal from the power supply device 9 outside the vehicle 2. Further, the control signals from the outside of the onboard charger 3 may be directly supplied to the switch 61, or may be for causing the control circuit 31 to output the control signal to the switch 61. The switch 61 is not an essential component and does not have to be provided.

The onboard charger 3 is configured to be electrically connectable to each of the load 8 and the power supply device 9 connected to the vehicle 2. Specifically, the onboard charger 3 is electrically connected to an alternating current (AC) socket or an onboard socket (not illustrated) of the vehicle 2 via the plurality of power supply lines L and N. The load 8 or the power supply device 9 is electrically connected to the AC socket of the vehicle 2 via a connection cable such as a charging cable, for example.

In the charging system 1, alternating current power from the external power supply device 9 is supplied to the plurality of power supply lines L and N when charging the vehicle 2. In addition, alternating current power based on direct current (DC) power from the battery 7 is supplied to the plurality of power supply lines L and N when discharging the vehicle 2. In other words, power from the power supply device 9 when charging the battery 7 and power from the battery 7 when discharging to the load 8 or the power supply device 9 are bidirectionally supplied to the plurality of power supply lines L and N.

As an example, single-phase alternating current power is supplied to the plurality of power supply lines L and N. For example, the power supply line L is a voltage line through which a single-phase current from a single-phase alternating current power supply flows. For example, the power supply line N is a neutral line electrically connected to each of the single-phase alternating current power supply and a ground potential.

As an example, the plurality of power supply lines L and N may be configured to be able to supply three-phase alternating current power. In this case, the power supply line L includes, for example, a plurality of power supply lines L1 to L3 (not illustrated). For example, the power supply line L1 is a voltage line through which the single-phase current from the single-phase alternating current power supply or, for example, a U-phase (first phase) current from a three-phase alternating current power supply flows. For example, the power supply line L2 is a voltage line that is not electrically connected to the single-phase alternating current power supply and through which, for example, a V-phase (second phase) current from the three-phase alternating current power supply flows. For example, the power supply line L3 is a voltage line that is not electrically connected to the single-phase alternating current power supply and through which, for example, a W-phase (third phase) current from the three-phase alternating current power supply flows. For example, the power supply line N is a neutral line electrically connected to each of the single-phase or three-phase alternating current power supply and a ground line of the ground potential. The ground line of the ground potential may be, for example, a ground line functionally grounded to a metal chassis or the like of the vehicle 2.

As an example, the AC socket (not illustrated) of the vehicle 2 is, for example, a power supply socket (inlet/outlet) for charging and discharging the vehicle 2. The AC socket is provided, for example, at a position available from the outside of the vehicle 2. For example, the AC socket is connected to the power supply device 9 when charging the vehicle 2. For example, the AC socket is connected to the load 8 or the power supply device 9 when discharging from the vehicle 2. As an example, the alternating current socket of the vehicle 2 supports both the single-phase alternating current power and the three-phase alternating current power. However, the alternating current socket of the vehicle 2 may support any one of the single-phase alternating current power and the three-phase alternating current power.

As an example, the onboard socket (not illustrated) of the vehicle 2 is a power supply socket (outlet) for discharging the vehicle 2. The onboard socket is provided, for example, in a compartment (vehicle interior) of the vehicle 2. For example, the onboard socket is connected to the load 8 when discharging from the vehicle 2. As an example, the onboard socket of the vehicle 2 supports the single-phase alternating current power. However, the onboard socket of the vehicle 2 may support both the single-phase alternating current power and the three-phase alternating current power.

The vehicle 2 may be, for example, various electric vehicles (EV) such as a battery electric vehicle (BEV), a hybrid electric vehicle (HEV), and a plug-in hybrid electric vehicle (PHEV). In addition, the vehicle 2 may be various moving bodies configured to be drivable using power from the mounted battery 7, such as a passenger car, a cargo vehicle, a van, a motorcycle, and an electric scooter.

The technique according to the embodiment is not limited to the onboard charger 3 mounted on the vehicle 2, and may be applied to various power conversion devices provided in, for example, an aircraft, a game facility, an uninterruptible power supply device, and the like.

The vehicle 2 may be configured to be able to operate onboard equipment (electrical component) by using, for example, power from the battery 7. Examples of the onboard equipment may include a navigation device, an audio device, an air conditioner, a power window, a defogger, an ECU, a global positioning system (GPS) module, an onboard camera, and the like.

The onboard charger 3 is a power conversion device mounted on the vehicle 2. The onboard charger 3 may be configured to be operable by, for example, any one of the single-phase alternating current power and the three-phase alternating current power. For example, the onboard charger 3 converts the single-phase or three-phase alternating current power supplied from the power supply device 9 into direct current power, and supplies the direct current power to the battery 7. Further, the onboard charger 3 converts direct current power from the battery 7 into alternating current power, and supplies the single-phase or three-phase alternating current power to the load 8 connected to the alternating current socket or the onboard socket (not illustrated) of the vehicle 2.

The onboard charger 3 does not have to support both the single-phase AC power and the three-phase AC power, and may be configured to be operable by any one of the single-phase AC power and the three-phase AC power. Further, the onboard charger 3 is not limited to operating by the single-phase alternating current power and the three-phase (multi-phase) alternating current power, and may be configured to be operable by two-phase (multi-phase) alternating current power.

The battery 7 is an example of an onboard battery mounted on the vehicle 2. The battery 7 stores power supplied from the power supply device 9 via the onboard charger 3. It is sufficient if the battery 7 can store power to be supplied to a traveling motor (main electric motor) or an electric component mounted on the vehicle 2, or the load 8 connected to the AC socket or the onboard socket (not illustrated) of the vehicle 2. As the battery 7, for example, any battery such as a lithium ion battery, a nickel hydrogen battery, or an all-solid-state battery can be appropriately used.

The load 8 is an example of an external load to which power from the battery 7 is supplied at the time of discharging. The load 8 is detachably connected to the AC socket or the onboard socket (not illustrated) of the vehicle 2. The load 8 may be an electronic device that receives power supplied from the vehicle 2, such as a home appliance or a smartphone. The load 8 may be an external power storage device or a power facility that receives power supplied from the vehicle 2, such as a home storage battery or a power purchase device of a charging station. The power purchase device of the charging station as the load 8 may be implemented by the power supply device 9.

The power supply device 9 is an example of an external power supply that supplies power to the battery 7 at the time of charging. The power supply device 9 is, for example, an arbitrary alternating current power supply such as a power supply mounted on a quick charging facility or a commercial power supply. The power supply device 9 is not limited to the single-phase alternating current power supply and the three-phase alternating current power supply (multi-phase alternating current power supply), and a two-phase alternating current power supply (multi-phase alternating current power supply) may be used. As an example, FIG. 1 illustrates a case where the single-phase alternating current power supply that supplies the single-phase alternating current power to the onboard charger 3 (power conversion device) of the vehicle 2 is used as the power supply device 9.

As illustrated in FIG. 1, the power supply device 9 includes an alternating current voltage source 91 and a switch 93. The alternating current voltage source 91 generates alternating current power to be supplied to the vehicle 2. The switch 93 is electrically connected between an output terminal of the power supply device 9 electrically connected to the power supply line L and the alternating current voltage source 91. The switch 93 operates according to a control pilot (CP) signal from the control circuit 31 to switch between conduction/disconnection between the alternating current voltage source 91 and the power supply line L. That is, the switch 93 switches between supply/non-supply of the alternating current power from the alternating current voltage source 91 to the power supply line L.

As illustrated in FIG. 1, the onboard charger 3 includes the control circuit 31, a power factor correction (PFC) circuit 32, and a DC-DC conversion circuit 33. The onboard charger 3 according to the present disclosure is not limited to the configuration of FIG. 1, and may have other configurations. For example, the power factor correction circuit 32 is not an essential component in the onboard charger 3, and another rectifying-smoothing circuit may be used.

The control circuit 31 controls an operation of the onboard charger 3. For example, the control circuit 31 acquires outputs (sensor values) of current sensors 321 and 331 and voltage sensors 323 and 333 before and after charging and discharging and during charging and discharging. For example, the control circuit 31 monitors the acquired sensor values. For example, the control circuit 31 outputs a control signal to control on/off of the power factor correction circuit 32 and the DC-DC conversion circuit 33 and a power amount of power conversion. For example, the control circuit 31 outputs a control signal to control on/off of the switches 61 and 93.

In addition, the control circuit 31 stops charging and discharging in a case where charge power or discharge power (charge/discharge power) exceeds a predetermined operation range. For example, in a case where the charge power supplied to the power supply lines L and N at the time of charging exceeds the operation range, the control circuit 31 outputs a control signal for stopping power conversion (charging operation) to the power factor correction circuit 32 and/or the DC-DC conversion circuit 33. Furthermore, for example, in a case where the charge power supplied to the power supply lines L and N at the time of charging exceeds the operation range, the control circuit 31 outputs, to the power supply device 9, a control signal (CP signal) for stopping the supply of the alternating current power to the power supply lines L and N, for example, after stopping the power conversion (charging operation). For example, in a case where the discharge power supplied to the power supply lines L and N at the time of discharging exceeds the operation range, the control circuit 31 outputs a control signal for stopping power conversion (discharging operation) to the power factor correction circuit 32 and/or the DC-DC conversion circuit 33.

After charging and discharging are stopped when the charge/discharge power exceeds the predetermined operation range, or when charging and discharging are not performed, the control circuit 31 acquires the sensor values from the current sensors 321 and 331 and the voltage sensors 323 and 333 in a state where power for charging and discharging (charge/discharge power) is not supplied to the power supply lines L and N. In addition, the control circuit 31 detects an abnormality of a corresponding sensor in a case where the sensor value in a state where the charge/discharge power is not supplied to the power supply lines L and N is different from an offset voltage. Detection of a sensor abnormality is described below.

The control circuit 31 includes, for example, at least one processor (not illustrated) and at least one memory (not illustrated), and has a hardware configuration using a normal computer. As the control circuit 31, for example, a digital signal processor (DSP) can be used. The control circuit 31 may implement each function of the control circuit 31 by, for example, the processor loading a program stored in a read only memory (ROM) or the like into a random access memory (RAM) and executing the loaded program, or may implement some or all of the functions with a dedicated hardware circuit (a semiconductor integrated circuit or the like).

The control circuit 31 that controls the operations of the power factor correction circuit 32 and the DC-DC conversion circuit 33 and the control circuit 31 that detects the sensor abnormality may be implemented by the same circuit or may be implemented by independent circuits different from each other.

The control circuit 31 may be implemented by an electronic control unit (ECU) provided inside the vehicle 2, a domain control unit (DCU) such as a cockpit domain controller (CDC) in which a plurality of ECUs are integrated, or a computer such as an on board unit (OBU). Furthermore, the control circuit 31 may transmit and receive information to and from another ECU mounted on the vehicle 2 via an onboard network including a controller area network (CAN), the Ethernet (registered trademark), a universal serial bus (USB) (registered trademark), or the like in the vehicle, and the load 8 or the power supply device 9 connected to the vehicle 2, or may communicate with an information processing device outside the vehicle 2 via a network such as the Internet.

The power factor correction circuit 32 is electrically connected between the AC socket or the onboard socket (not illustrated) of the vehicle 2 and the DC-DC conversion circuit 33 via the plurality of power supply lines L and N. For example, when charging the battery 7, the power factor correction circuit 32 performs rectification and smoothing on an alternating current voltage from the power supply device 9 to generate a direct current voltage. For example, when discharging the battery 7, the power factor correction circuit 32 generates an alternating current voltage by using the direct current voltage from the DC-DC conversion circuit 33.

The DC-DC conversion circuit 33 is electrically connected between the power factor correction circuit 32 and the battery 7 via the plurality of power supply lines L and N. For example, when charging the battery 7, the DC-DC conversion circuit 33 converts the direct current voltage generated by the power factor correction circuit 32 into an alternating current voltage again, and then performs rectification and smoothing to generate a direct current voltage of an arbitrary set voltage. For example, when discharging the battery 7, the DC-DC conversion circuit 33 converts a direct current voltage from the battery 7 into an alternating current voltage, and then performs rectification and smoothing to generate a direct current voltage of an arbitrary set voltage.

The onboard charger 3 may further include a noise filter (not illustrated) that suppresses (removes) intrusion of noise from the power supply device 9 and emission of noise to the power supply device 9. The noise filter is provided, for example, between the AC socket or the onboard socket (not illustrated) of the vehicle 2 and the power factor correction circuit 32, and may also be provided at another position.

Here, the power factor correction circuit 32 and the DC-DC conversion circuit 33 according to the embodiment are examples of power conversion circuits. The power conversion circuit that converts alternating current power supplied from the power supply device 9 to the plurality of power supply lines L and N into direct current power when charging the battery 7, and the power conversion circuit that converts direct current power supplied from the battery 7 to the plurality of power supply lines L and N into alternating current power when discharging to the load 8 or the power supply device 9 may have a common circuit configuration or partially or entirely different circuit configurations.

As illustrated in FIG. 1, each of the power factor correction circuit 32 and the DC-DC conversion circuit 33 may include at least one sensor. FIG. 1 illustrates the current sensor 321 and the voltage sensor 323 as the sensors provided in the power factor correction circuit 32. In addition, FIG. 1 illustrates the current sensor 331 and the voltage sensor 333 as the sensors provided in the DC-DC conversion circuit 33.

The current sensors 321 and 331 and the voltage sensors 323 and 333 may be sensors provided in the onboard charger 3 as external constituent elements of the power factor correction circuit 32 and the DC-DC conversion circuit 33.

Further, each of the current sensors 321 and 331 and the voltage sensors 323 and 333 relates to the power factor correction circuit 32 and the DC-DC conversion circuit 33, and is provided on at least one of the battery 7 side and the load 8 side or the power supply device 9 side. That is, the current sensor 331 and the voltage sensor 333 do not have to be provided on the battery 7 side of the onboard charger 3. Alternatively, the current sensor 321 and the voltage sensor 323 do not have to be provided on the load 8 side or the power supply device 9 side of the onboard charger 3. Alternatively, the current sensor may be provided on at least one of the battery 7 side and the load 8 side or the power supply device 9 side, and the voltage sensor may be provided on the other side.

Here, each of the current sensors 321 and 331 and the voltage sensors 323 and 333 is an example of a sensor electrically connected to the power supply lines L and N. In addition, each of the current sensors 321 and 331 and the voltage sensors 323 and 333 is an example of a sensor that has an output offset such that a sensor value of the applied offset voltage is output in a state where the charge/discharge power is not supplied to the power supply lines L and N. In addition, each of the current sensors 321 and 331 and the voltage sensors 323 and 333 is an example of a sensor configured to output a sensor value corresponding to a current or a voltage of the charge/discharge power supplied to the power supply lines L and N.

### (Current Sensor)

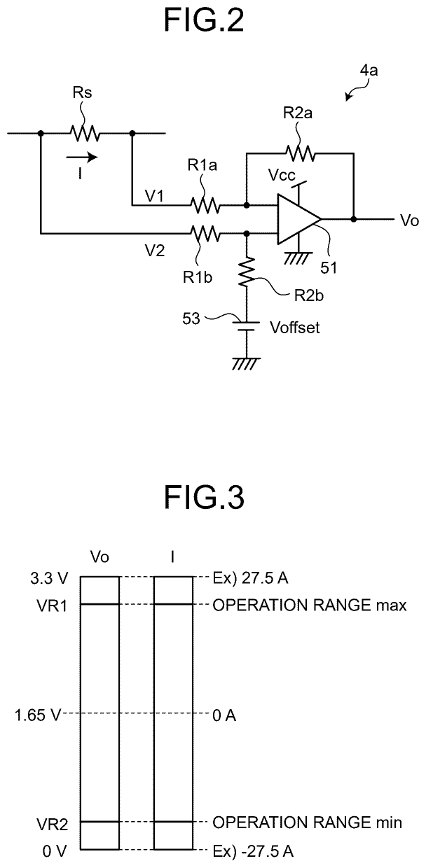

FIG. 2 is a diagram illustrating an example of a configuration of a sensor 4a that implements the current sensors 321 and 331 of FIG. 1. As illustrated in FIG. 2, the sensor 4a is a current sensor configured to be able to detect a current value of a current flowing through the power supply line L by using a shunt resistor Rs and an amplifier 51 (differential amplifier). The sensor 4a may be a current sensor configured to be able to detect the current value by using a Hall sensor.

In the example of FIG. 2, the sensor 4a includes the shunt resistor Rs, a first resistor R1a, a second resistor R2a, a third resistor R1b, a fourth resistor R2b, the amplifier 51, and an offset voltage source 53. Here, the shunt resistor Rs is a resistor element having a resistance value Rs. The first resistor R1a and the third resistor R1b are resistor elements having a first resistance value R1. The second resistor R2a and the fourth resistor R2b are resistors having a second resistance value R2. The offset voltage source 53 is a voltage source that generates an offset voltage Voffset.

The shunt resistor Rs is electrically connected in series to the power supply line L. The shunt resistor Rs is electrically connected in parallel to a pair of input terminals of the amplifier 51. Specifically, one of the pair of input terminals of the amplifier 51 is electrically connected to one end of the shunt resistor Rs via the first resistor R1a. One of the pair of input terminals of the amplifier 51 is electrically connected to an output terminal of the amplifier 51 via the second resistor R2a. Similarly, the other of the pair of input terminals of the amplifier 51 is electrically connected to the other end of the shunt resistor Rs via the third resistor R1b. The other of the pair of input terminals of the amplifier 51 is electrically connected to one end of the offset voltage source 53 via the fourth resistor R2b. The other end of the offset voltage source 53 is electrically connected to the ground line of the ground potential. The output terminal of the amplifier 51 is electrically connected to the control circuit 31. In addition, a pair of power supply terminals of the amplifier 51 is electrically connected between a wiring of a high-side power supply voltage VCC of the sensor 4a and the ground line of the ground potential (a wiring of a low-side power supply voltage VEE). That is, the power supply voltage VCC of the sensor 4a provides a high-side power supply potential for the amplifier 51. Similarly, the ground line of the ground potential provides a low-side power supply potential for the amplifier 51.

FIG. 3 is a diagram for describing detection of a sensor abnormality based on an operation range related to the sensor 4a that implements the current sensors 321 and 331 of FIG. 1. In the example of FIG. 3, the high-side and low-side power supply potentials for the amplifier 51 are 3.3 (V) and 0 (V), respectively. The offset voltage Voffset is 1.65 (V).

The sensor 4a is configured to output, as the sensor value, a voltage value Vo corresponding to a current value I of a current (charge/discharge current) of the charge/discharge power supplied to the power supply line L, as expressed by the following formula. In the sensor 4a, the offset voltage Voffset is applied to one of the pair of input terminals of the amplifier 51. Therefore, the sensor 4a has the output offset such that the voltage value Vo of the offset voltage Voffset is output as the sensor value in a state where the charge/discharge current is not supplied to the power supply line L.

$$Vo = Rs \times I \times \frac{R 2}{R 1} + Voffset \qquad ( 1 )$$

For example, in a case where a current of 27.5 (A) or more flows through the power supply line L, the voltage value Vo (sensor value) from the sensor 4a is 3.3 (V) as the high-side power supply potential for the amplifier 51. For example, in a case where a current of an upper limit value (operation range max) of the operation range of the charge/discharge current of the onboard charger 3 flows through the power supply line L, the voltage value Vo (sensor value) from the sensor 4a is VR1 (V) as a first voltage value. VR1 (V) as the first voltage value corresponding to the charge/discharge current of the operation range max is lower than the high-side power supply voltage VCC of the sensor 4a and higher than the offset voltage Voffset. In the present disclosure, the first voltage value corresponding to the charge/discharge current of the operation range max is an example of a detection range max.

For example, in a case where the charge/discharge current does not flow through the power supply line L (I=0 (A)), the voltage value Vo (sensor value) from the sensor 4a is 1.65 (V) as the offset voltage Voffset.

For example, in a case where a current of a lower limit value (operation range min) of the operation range of the charge/discharge current of the onboard charger 3 flows through the power supply line L, the voltage value Vo (sensor value) from the sensor 4a is VR2 (V) as a second voltage value. VR2 (V) as the second voltage value corresponding to the charge/discharge current of the operation range min is higher than the low-side power supply voltage VEE (for example, 0 (V) as the ground potential) and lower than the offset voltage Voffset. In the present disclosure, the second voltage value corresponding to the charge/discharge current of the operation range min is an example of a detection range min.

For example, in a case where a current of −27.5 (A) or less flows through the power supply line L, the voltage value Vo (sensor value) from the sensor 4a is 0 (V) as the low-side power supply potential VEE for the amplifier 51.

In a state where the charge/discharge power is not supplied to the power supply lines L and N, that is, in a state of I=0 (A) in which the charge/discharge current does not flow through the power supply line L, a voltage value of Vo=1.65 (V) is output as the sensor value as expressed by Formula (1). Under such a circumstance, in a case where the sensor abnormality occurs and the voltage value Vo output as the sensor value is short-circuited to the ground potential (power supply voltage VEE) or the power supply voltage VCC, even in a state where I=0 (A), the charge/discharge current indicated by the sensor value becomes the operation range min or less or the operation range max or more. That is, even in a state where I=0 (A), the sensor value is equal to or lower than the detection range min or equal to or higher than the detection range max.

Therefore, the control circuit 31 detects a power supply fault (sensor abnormality) of the sensor 4a in a case where the sensor value in a state where the charge/discharge current does not flow through the power supply line L is equal to or higher than the first voltage value VR1 (detection range max), such as the high-side power supply potential (power supply voltage VCC) for the amplifier 51. Similarly, the control circuit 31 detects a ground fault (sensor abnormality) of the sensor 4a in a case where the sensor value in a state where the charge/discharge current does not flow through the power supply line L is equal to or lower than the second voltage value VR2 (detection range min), such as the low-side power supply potential (ground potential) for the amplifier 51.

As described above, the control circuit 31 can detect the sensor abnormality such as the power supply fault or the ground fault of the sensor 4a that implements the current sensors 321 and 331 based on the operation range of the charge/discharge current of the onboard charger 3. In addition, the control circuit 31 can determine whether an output of the high-side or low-side power supply voltage is caused by the sensor abnormality such as the power supply fault or the ground fault or is a measured value corresponding to the current value for each of current directions bidirectional to cope with both charging/discharging.

### (Voltage Sensor)

Here, differences from the sensor 4a of FIG. 2 will be mainly described, and redundant description is appropriately omitted.

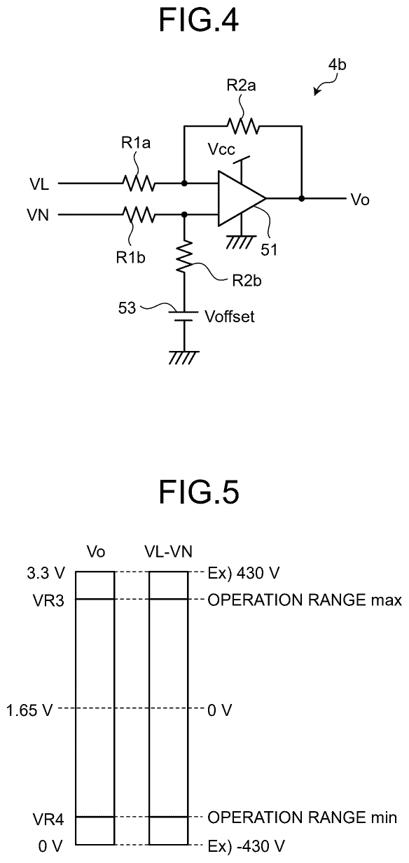

FIG. 4 is a diagram illustrating an example of a configuration of a sensor 4b that implements the voltage sensors 323 and 333 of FIG. 1. The sensor 4b is a voltage sensor configured to be able to detect a voltage value of a voltage applied between the plurality of power supply lines L and N using an amplifier 51. As illustrated in FIG. 4, the sensor 4b has the same configuration as the sensor 4a in FIG. 2 except that the shunt resistor Rs is not provided. The sensor 4b may be constructed as a voltage follower circuit. Each resistance value and an offset voltage value of the sensor 4b may be the same as or different from each resistance value and the offset voltage value of the sensor 4a.

In the example of FIG. 4, the sensor 4b includes a first resistor R1a, a second resistor R2a, a third resistor R1b, a fourth resistor R2b, the amplifier 51, and an offset voltage source 53. One of a pair of input terminals of the amplifier 51 is electrically connected to the power supply line L via the first resistor R1a. One of the pair of input terminals of the amplifier 51 is electrically connected to an output terminal of the amplifier 51 via the second resistor R2a. Similarly, the other of the pair of input terminals of the amplifier 51 is electrically connected to the power supply line N via the third resistor R1b. The other of the pair of input terminals of the amplifier 51 is electrically connected to one end of the offset voltage source 53 via the fourth resistor R2b.

FIG. 5 is a diagram for describing detection of a sensor abnormality based on an operation range related to the sensor 4b that implements the voltage sensors 323 and 333 of FIG. 1. In the example of FIG. 5, high-side and low-side power supply potentials for the amplifier 51 and an offset voltage Voffset are the same as those in the example of FIG. 2, but the high-side and low-side power supply potentials for the amplifier 51 and the offset voltage Voffset may be different from those in the example of FIG. 2.

The sensor 4b is configured to output, as the sensor value, a voltage value Vo corresponding to a voltage value (VL−VN) of the voltage (charge/discharge voltage) of the charge/discharge power supplied to the plurality of power supply lines L and N, as expressed by the following formula. In the sensor 4b, the offset voltage Voffset is applied to one of the pair of input terminals of the amplifier 51. Therefore, the sensor 4b has the output offset such that the voltage value Vo of the offset voltage Voffset is output as the sensor value in a state where the charge/discharge voltage is not applied between the plurality of power supply lines L and N.

$$Vo = ( {V}_{L} - {V}_{N} ) \times \frac{R 2}{R 1} + Voffset \qquad ( 2 )$$

For example, in a case where a voltage of 430 (V) or more is applied between the plurality of power supply lines L and N, the voltage value Vo (sensor value) from the sensor 4b is 3.3 (V) as the high-side power supply potential for the amplifier 51. For example, in a case where a voltage of an upper limit value (operation range max) of the operation range of the charge/discharge voltage of the onboard charger 3 is applied between the plurality of power supply lines L and N, the voltage value Vo (sensor value) from the sensor 4b is VR3 (V) as a third voltage value. VR3 (V) as the third voltage value corresponding to the charge/discharge voltage of the operation range max is lower than the high-side power supply voltage VCC of the sensor 4b and higher than the offset voltage Voffset. In the present disclosure, the third voltage value corresponding to the charge/discharge voltage of the operation range max is an example of the detection range max.

For example, in a case where the charge/discharge voltage is not applied between the plurality of power supply lines L and N, the voltage value Vo (sensor value) from the sensor 4b is 1.65 (V) as the offset voltage Voffset.

For example, in a case where a voltage of a lower limit value (operation range min) of the operation range of the charge/discharge voltage of the onboard charger 3 is applied between the plurality of power supply lines L and N, the voltage value Vo (sensor value) from the sensor 4b is VR4 (V) as a fourth voltage value. VR4 (V) as the fourth voltage value corresponding to the charge/discharge voltage of the operation range min is higher than the low-side power supply voltage VEE (for example, 0 (V) as the ground potential) and lower than the offset voltage Voffset. In the present disclosure, the fourth voltage value corresponding to the charge/discharge voltage of the operation range min is an example of the detection range min.

For example, in a case where a voltage of −430 (V) or less is applied between the plurality of power supply lines L and N, the voltage value Vo (sensor value) from the sensor 4b is 0 (V) as the low-side power supply potential VEE for the amplifier 51.

In a state where the charge/discharge power is not supplied to the power supply lines L and N, that is, in a state of VL=VN=0 (V) in which the charge/discharge voltage is not applied between the plurality of power supply lines L and N, a voltage value of Vo=1.65 (V) is output as the sensor value as expressed by Formula (2). Under such a circumstance, in a case where the sensor abnormality occurs and the voltage value Vo output as the sensor value is short-circuited to the ground potential (power supply voltage VEE) or the power supply voltage VCC, even in a state where VL=VN=0 (V), the charge/discharge current indicated by the sensor value becomes the operation range min or less or the operation range max or more. That is, even in a state where VL=VN=0 (V), the sensor value is equal to or lower than the detection range min or equal to or higher than the detection range max.

Therefore, the control circuit 31 detects a power supply fault (sensor abnormality) of the sensor 4b in a case where the sensor value in a state where the charge/discharge voltage is not applied between the plurality of power supply lines L and N is equal to or higher than the third voltage value VR3 (detection range max), such as the high-side power supply potential (power supply voltage VCC) for the amplifier 51. Similarly, the control circuit 31 detects a ground fault (sensor abnormality) of the sensor 4b in a case where the sensor value in a state where the charge/discharge voltage is not applied between the plurality of power supply lines L and N is equal to or lower than the fourth voltage value VR4 (detection range min), such as the low-side power supply potential (ground potential) for the amplifier 51.

As described above, the control circuit 31 can detect the sensor abnormality such as the power supply fault or the ground fault of the sensor 4b that implements the voltage sensors 323 and 333 based on the operation range of the charge/discharge voltage of the onboard charger 3.

Next, abnormality detection processing executed in the charging system 1 configured as described above will be described.

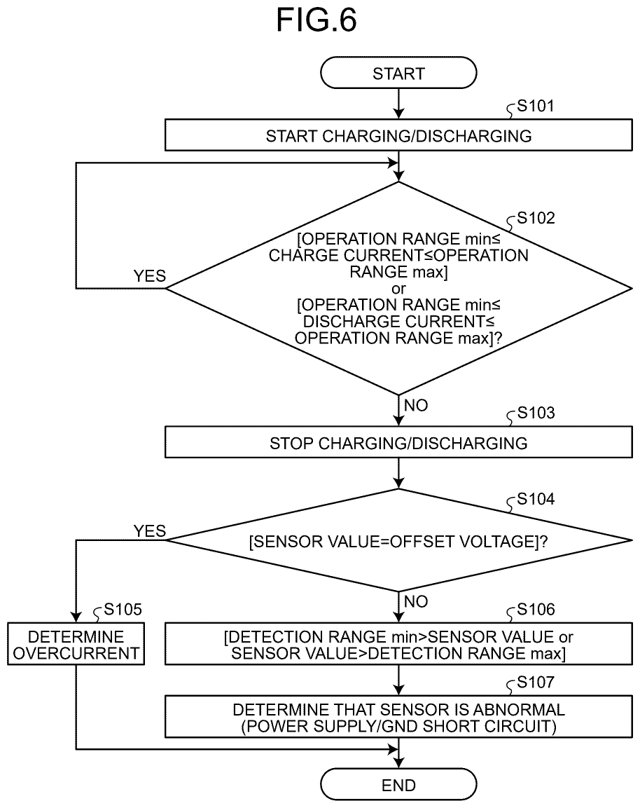

FIG. 6 is a flowchart illustrating an example of a flow of processing of detecting a power supply fault abnormality or a ground fault abnormality (sensor abnormality) of the sensor 4a that implements the current sensors 321 and 331 executed by the control circuit 31 of FIG. 1.

First, the control circuit 31 starts charging or discharging (charging/discharging) (S101). Then, the control circuit 31 acquires the sensor value from the sensor 4a, and determines whether or not a charge/discharge current I indicated by the detected sensor value is within the operation range (S102). Here, whether or not the charge/discharge current I is within the operation range is whether or not the charge/discharge current I is equal to or higher than the operation range min and equal to or lower than the operation range max. The determination is not necessarily performed by converting the detected sensor value into the charge/discharge current I, and may be performed by determining whether or not the sensor value is equal to or higher than the detection range max and equal to or lower than the detection range min. In the sensor 4a that implements the current sensor 321, the charge/discharge current I is an AC current. In the sensor 4a that implements the current sensor 331, the charge/discharge current I is a DC current. In a case where the charge/discharge current is within the operation range (S102: Yes), the flow of FIG. 6 repeats the processing of S102, for example, until the charging/discharging is completed.

In a case where the charge/discharge current is not within the operation range (S102: No), the control circuit 31 stops the charging/discharging (S103). That is, the control circuit 31 stops a charging/discharging operation in a case where the charge/discharge current I exceeds the operation range max or is lower than the operation range min. Then, the control circuit 31 determines whether or not the charge/discharge current I indicated by the sensor value in a state where the charge/discharge current I does not flow through the power supply line L is 0 “A”, that is, whether or not the sensor value in a state where the charge/discharge current I does not flow through the power supply line L is the offset voltage Voffset (S104).

In a case where the detected charge/discharge current I is 0 “A”, that is, in a case where the sensor value of the charge/discharge current I is the offset voltage Voffset (S104: Yes), the control circuit 31 detects an overcurrent. In a case where a peak value of the charge/discharge current I indicated by the detected sensor value is low, for example, in a case where an absolute value of a difference between the sensor value and the offset voltage Voffset is smaller than a predetermined threshold, the control circuit 31 may detect a current decrease (low current). The predetermined threshold is, for example, smaller than an absolute value of the detection range max or the detection range min. Thereafter, the flow of FIG. 6 ends, and when the charging/discharging is resumed, the processing is executed again.

As described above, in the sensor abnormality detection processing according to the present embodiment, the sensor abnormality is not detected in a case where the sensor value in a state where the charge/discharge current I does not flow through the power supply line L is the offset voltage Voffset indicating that the charge/discharge current I is 0 “A”.

On the other hand, in a case where the detected charge/discharge current I is different from 0 “A”, that is, in a case where the sensor value of the charge/discharge current I is different from the offset voltage Voffset (S104: No), the control circuit 31 determines that the sensor value of the charge/discharge current I is higher than the detection range max or lower than the detection range min (S106). That is, the control circuit 31 determines that the charge/discharge current I higher than the operation range max or lower than the operation range min is detected. In this case, the control circuit 31 determines that the sensor is abnormal (S107). Specifically, in a case where the sensor value of the charge/discharge current I is higher than the detection range max, that is, in a case where the detected charge/discharge current I is higher than the operation range max, the control circuit 31 detects a sensor abnormality of a power supply short circuit (power supply fault abnormality). In a case where the sensor value of the charge/discharge current I is lower than the detection range min, that is, in a case where the detected charge/discharge current I is lower than the operation range min, the control circuit 31 detects a sensor abnormality of a GND short circuit (ground fault abnormality). Thereafter, the flow of FIG. 6 ends.

As described above, in the sensor abnormality detection processing according to the present embodiment, in a case where the sensor value in a state where the charge/discharge current I does not flow through the power supply line L is different from the offset voltage Voffset indicating that the charge/discharge current I is 0 “A”, the power supply fault abnormality or the ground fault abnormality (sensor abnormality) is detected.

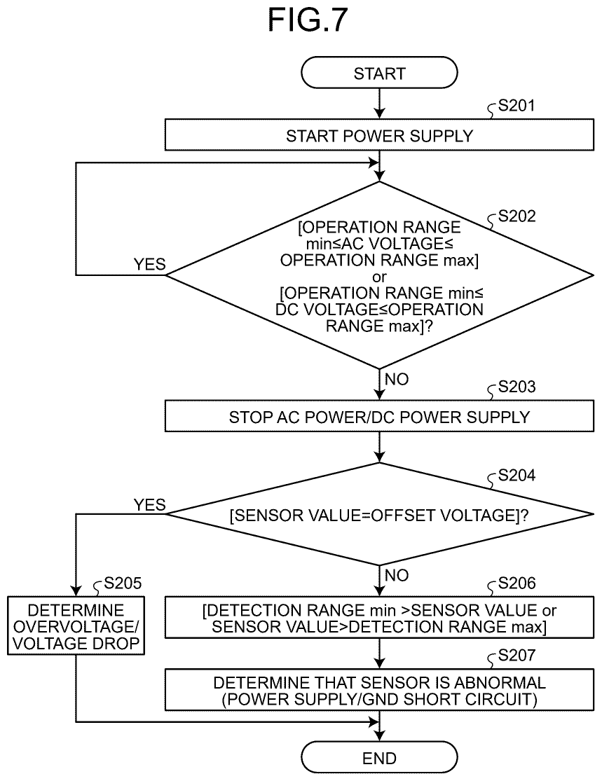

FIG. 7 is a flowchart illustrating an example of a flow of processing of detecting the power supply fault abnormality or the ground fault abnormality (sensor abnormality) of the sensor 4b that implements the voltage sensors 323 and 333 executed by the control circuit of FIG. 1.

First, the control circuit 31 starts power supply to the plurality of power supply lines L and N, and starts charging or discharging (charging/discharging) (S201). Then, the control circuit 31 acquires the sensor value from the sensor 4b, and determines whether or not the charge/discharge voltage is within the operation range (S202). Here, whether or not the charge/discharge voltage is within the operation range is whether or not the charge/discharge voltage is equal to or higher than the operation range min and equal to or lower than the operation range max. The determination is not necessarily performed by converting the detected sensor value into the charge/discharge voltage, and may be performed by determining whether or not the sensor value is equal to or higher than the detection range max and equal to or lower than the detection range min. In the sensor 4b that implements the voltage sensor 323, the charge/discharge voltage is an alternating current (AC) voltage. In the sensor 4b that implements the voltage sensor 333, the charge/discharge voltage is a direct current (DC) voltage. In a case where the charge/discharge voltage is within the operation range (S202: Yes), the flow of FIG. 7 repeats the processing of S202, for example, until the charging/discharging is completed.

In a case where the charge/discharge voltage is not within the operation range (S202: No), the control circuit 31 stops the supply of the alternating current power or the direct current power to the plurality of power supply lines L and N, and stops the charging/discharging (S203). That is, the control circuit 31 stops a charging/discharging operation in a case where the charge/discharge voltage exceeds the operation range max or is lower than the operation range min. Then, the control circuit 31 determines whether or not the charge/discharge voltage indicated by the sensor value in a state where the charge/discharge voltage is not applied between the plurality of power supply lines L and N is 0 “V”, that is, whether or not the sensor value in a state where the charge/discharge voltage is not applied between the plurality of power supply lines L and N is the offset voltage Voffset (S204).

In a case where the detected charge/discharge voltage is 0 “V”, that is, in a case where the sensor value of the charge/discharge voltage is the offset voltage Voffset (S204: Yes), the control circuit 31 detects an overvoltage. In a case where a peak value of the charge/discharge voltage indicated by the detected sensor value is low, for example, in a case where an absolute value of a difference between the sensor value and the offset voltage Voffset is smaller than a predetermined threshold, the control circuit 31 may detect a voltage drop (low voltage). The predetermined threshold is, for example, smaller than an absolute value of the detection range max or the detection range min. Thereafter, the flow of FIG. 7 ends, and when the charging/discharging is resumed, the processing is executed again.

As described above, in the sensor abnormality detection processing according to the present embodiment, the sensor abnormality is not detected in a case where the sensor value in the state where the charge/discharge voltage is not applied between the plurality of power supply lines L and N is the offset voltage Voffset indicating that the charge/discharge voltage is 0 “V”.

On the other hand, in a case where the detected charge/discharge voltage is different from 0 “V”, that is, in a case where the sensor value of the charge/discharge voltage is different from the offset voltage Voffset (S204: No), the control circuit 31 determines that the sensor value of the charge/discharge voltage is higher than the detection range max or lower than the detection range min (S206). That is, the control circuit 31 determines that the charge/discharge voltage higher than the operation range max or lower than the operation range min is detected. In this case, the control circuit 31 determines that the sensor is abnormal (S207). Specifically, in a case where the sensor value of the charge/discharge voltage is higher than the detection range max, that is, in a case where the detected charge/discharge voltage is higher than the operation range max, the control circuit 31 detects the sensor abnormality of the power supply short circuit (power supply fault abnormality). In a case where the sensor value of the charge/discharge voltage is lower than the detection range min, that is, in a case where the detected charge/discharge voltage is lower than the operation range min, the control circuit 31 detects the sensor abnormality of the GND short circuit (ground fault abnormality). Thereafter, the flow of FIG. 7 ends.

As described above, in the sensor abnormality detection processing according to the present embodiment, in a case where the sensor value in a state where the charge/discharge voltage is not applied between the plurality of power supply lines L and N is different from the offset voltage Voffset indicating that the charge/discharge voltage is 0 “V”, the power supply fault abnormality or the ground fault abnormality (sensor abnormality) is detected.

FIGS. 6 and 7 illustrate a case where the processing is executed during the charging/discharging, but the present invention is not limited thereto. The detection of the sensor abnormality may be performed at the start or end of the charging/discharging, may be periodically performed during a period in which the charging/discharging is not performed before the start of the charging/discharging or after the end of the charging/discharging, or may be always or intermittently performed during the charging/discharging. However, in a case where the sensor abnormality is detected during a period in which the charging/discharging is not performed before the start including the start of the charging/discharging or after the end including the end of the charging/discharging, the steps of processing of S101 to S103 of FIG. 6 or the steps of processing of S201 to S203 of FIG. 7 are not executed.

As described above, in the charging system 1 according to the present embodiment, predetermined offset voltages are set in the sensors 4a and 4b. In addition, the control circuit 31 acquires the sensor values from the sensors 4a and 4b in a state where the charge/discharge power is not supplied to the plurality of power supply lines L and N. Then, based on whether or not the sensor value is different from the offset voltage Voffset, the control circuit 31 determines whether the abnormality of the charge/discharge power, such as the overcurrent, the overvoltage, or the voltage drop, is detected by the normal sensors 4a and 4b, or the sensor is abnormal. Specifically, in the charging system 1 according to the present embodiment, the control circuit 31 detects the sensor abnormality in a case where the sensor values from the sensors 4a and 4b in a state where the charge/discharge power is not supplied to the plurality of power supply lines L and N are different from the offset voltage Voffset.

Hitherto, in the onboard charger 3, there is a risk that the power supply device 9 connected to an input side, the battery 7 connected to an output side, and an onboard component are destroyed when a monitored sensor value becomes inaccurate and an overcurrent in which an input/output current value exceeds a request current occurs or an overvoltage in which an input/output voltage value exceeds an upper limit value occurs. In addition, there is a possibility that the battery 7 cannot be charged or the load 8 does not operate when the monitored sensor value becomes inaccurate and a voltage drop in which the input/output voltage value falls below a lower limit value occurs. Therefore, in the onboard charger 3, it is necessary to constantly monitor whether or not the current sensors 321 and 331 and the voltage sensors 323 and 333 are normally operating.

However, when another sensor is added as a redundant sensor in order to monitor a sensor abnormality, there is a problem that costs increase or a component mounting area increases due to the addition. Therefore, there is a demand for a technique for detecting a sensor abnormality without adding a redundant sensor. In addition, since the current directions are bidirectional to cope with both charging/discharging, even when the sensor value is 0 (V) in a state where the charge/discharge power is not supplied to the plurality of power supply lines L and N (I=0 (A), and VL=VN=0 (V)), it is not possible to determine whether a sensor abnormality has occurred or an abnormality in power has been detected by a normal sensor.

Under such a circumstance, in the charging system 1 according to the present embodiment, the control circuit 31 can determine that the sensors 4a and 4b have the power supply fault/ground fault abnormality in a case where the charge/discharge voltage or the charge/discharge current based on the sensor value from the sensor 4a or 4b for which the predetermined offset voltage is set is not 0 even though the charging/discharging is not performed, for example, after the charging/discharging operation is stopped. Therefore, with the charging system 1 according to the present embodiment, it is possible to detect (monitor) a sensor abnormality without adding a redundant sensor. In addition, it is possible to determine whether a sensor abnormality has occurred or an abnormality in power has been detected by a normal sensor in a case where the charge/discharge voltage or the charge/discharge current based on the sensor value is not 0 even though the charging/discharging is not performed.

### Second Embodiment

In the above embodiment, the charging system 1 capable of detecting the power supply fault/ground fault abnormality as the sensor abnormality based on the sensor value in a state where the charging/discharging is not performed and the operation range of the charge/discharge power has been described, but the present invention is not limited thereto. The sensor abnormality is not limited to a case where the power supply short circuit or the GND short circuit occurs, and a gain error in which a gain abnormality occurs and the sensor value becomes inaccurate is also conceivable.

Therefore, in the present embodiment, a charging system 1 capable of detecting the gain error as the sensor abnormality will be described. In the present embodiment, differences from the first embodiment will be mainly described, and redundant description is appropriately omitted.

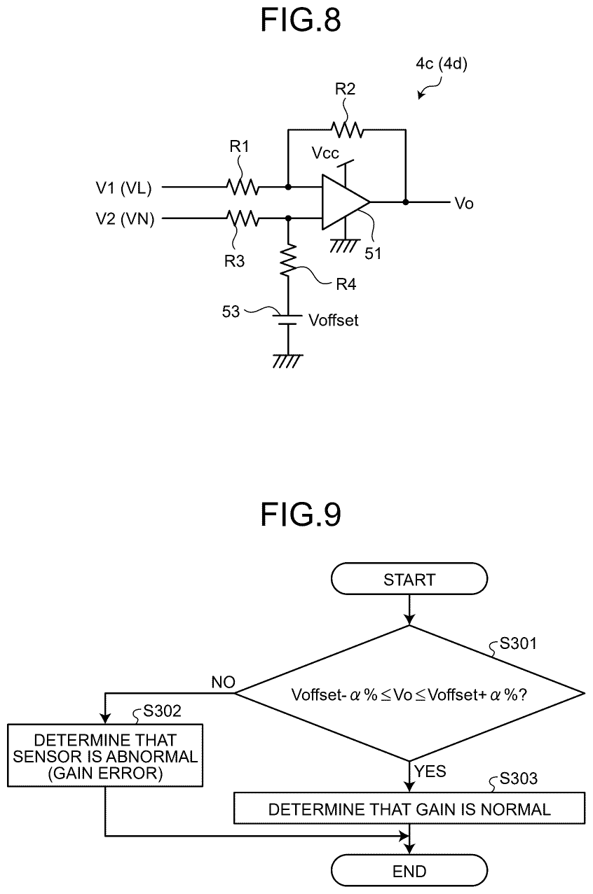

FIG. 8 is a diagram illustrating an example of a configuration of a sensor 4c that implements the current sensors 321 and 331 of FIG. 1 or a sensor 4d that implements the voltage sensors 323 and 333 of FIG. 1.

In the example of FIG. 8, the sensor 4c is the same as the sensor 4a of FIG. 2 except that the first resistor R1a having the first resistance value R1, the second resistor R2a having the second resistance value R2, the third resistor R1b having the first resistance value R1, and the fourth resistor R2b having the second resistance value R2 are expressed as a first resistor R1 having a first resistance value R1, a second resistor R2 having a second resistance value R2, a third resistor R3 having the first resistance value R1, and a fourth resistor R4 having the second resistance value R2, respectively. The sensor 4d has the same configuration as the sensor 4c except that a shunt resistor Rs is not provided. Each resistance value and an offset voltage value of the sensor 4d may be the same as or different from each resistance value and an offset voltage value of the sensor 4c.

The sensor 4c is configured to output, as a sensor value, a voltage value Vo corresponding to a voltage (V1−V2) between shunt resistors generated in the shunt resistor Rs by a current value I of a current (charge/discharge current) of charge/discharge power supplied to a power supply line L, as expressed by the following formula. In the sensor 4c, an offset voltage Voffset is applied to one of a pair of input terminals of an amplifier 51. The resistance values of the first to fourth resistors R1 to R4 are designed such that R1=R2 and R3=R4. Therefore, the sensor 4c has an output offset such that the voltage value Vo of the offset voltage Voffset is output as the sensor value in a case where charging/discharging is stopped, and I=0 (A) or V1=V2=0 (V).

$$Vo = \frac{R 2}{R 1} V 1 - \frac{R 4 ( R 1 + R 2 )}{R 1 ( R 3 + R 4 )} V 2 + \frac{R 3 ( R 1 + R 2 )}{R 1 ( R 3 + R 4 )} Voffset \qquad ( 3 )$$

Meanwhile, in a case where a power supply fault abnormality in which the sensor value is short-circuited to a high-side power supply voltage VCC or a ground fault abnormality in which the sensor value is short-circuited to a low-side power supply voltage VEE (ground potential) occurs, the voltage value Vo becomes the high-side or low-side power supply voltage. Therefore, a control circuit 31 according to the present embodiment can detect the power supply fault abnormality or the ground fault abnormality as the sensor abnormality, similarly to the first embodiment.

In addition, in a case where an abnormality of the respective resistance values of the first to fourth resistors R1 to R4, that is, a gain abnormality, occurs, the expression R1=R2 or R3=R4 is not satisfied. Therefore, a coefficient of the third term on the right side of Formula (3) does not become 1, and the voltage value Vo is out of a predetermined variation range of the offset voltage Voffset. Here, the variation range of the offset voltage Voffset is an example of a predetermined range based on the offset voltage Voffset. For example, the variation range of the offset voltage Voffset is determined in advance based on individual differences of the respective resistance values of the first to fourth resistors R1 to R4, and is stored in an internal memory of the control circuit 31 or the like.

Therefore, the control circuit 31 detects the gain error (sensor abnormality) of the sensor 4c in a case where the sensor value in a state where the charge/discharge current does not flow through the power supply line L is out of the variation range of the offset voltage Voffset.

The sensor 4d will be described by replacing V2 with VL (L-phase voltage) and V1 with VN (N-phase voltage). That is, the control circuit 31 detects the gain error (sensor abnormality) of the sensor 4d in a case where the sensor value in a state where a charge/discharge voltage is not applied between a plurality of power supply lines L and N is out of the variation range of the offset voltage Voffset. The sensors 4c and 4d may have a common variation range or different variation ranges.

FIG. 9 is a flowchart illustrating an example of a flow of processing of detecting the gain error (sensor abnormality) of the sensor 4a that implements the current sensors 321 and 331 or the sensor 4d that implements the voltage sensors 323 and 333, executed by the control circuit 31 of FIG. 1.

The flow of FIG. 9 is executed at the start or end of the charging/discharging, or during a period in which the charging/discharging is not performed before the start of the charging/discharging or after the end of the charging/discharging. That is, the flow of FIG. 9 is started, for example, in a state where a switch 61 of an onboard charger 3 and a switch 93 of a power supply device 9 are turned off. The flow of FIG. 9 may be executed as a series of flows prior to the flow of FIG. 6 or 7, for example, or may be independently executed at a different timing.

The control circuit 31 determines whether or not the voltage value Vo output as the sensor value is within the variation range (±α (%)) of the offset voltage Voffset (S301).

In a case where the voltage value Vo is out of the variation range of the offset voltage Voffset (S301: No), the control circuit 31 detects the gain error as the sensor abnormality (S302). Thereafter, the flow of FIG. 9 ends.

On the other hand, in a case where the voltage value Vo is within the variation range of the offset voltage Voffset (S301: Yes), the control circuit 31 determines that the gain is normal (S303). Thereafter, the flow of FIG. 9 ends.

As described above, the charging system 1 according to the present embodiment monitors whether or not the sensor value in a state where the charge/discharge power is not supplied to the plurality of power supply lines L and N before the start of charging is within the variation range of the offset voltage Voffset. Then, the charging system 1 according to the present embodiment detects the gain error (sensor abnormality) in a case where the sensor value in a state where the charge/discharge power is not supplied to the plurality of power supply lines L and N is out of the variation range of the offset voltage Voffset. With such a configuration, it is possible to detect the presence or absence of occurrence of a sensor abnormality and a type of the sensor abnormality based on the sensor value when the charging/discharging is stopped without using a redundant sensor.

In the description according to each embodiment described above, the numerical values of the ranges of the current and the voltage corresponding to the offset voltage Voffset, the power supply voltages VCC and VEE, and the voltage value Vo (sensor value) of the sensor 4 are merely examples, and can be appropriately set.

In each embodiment described above, determination of “whether or not it is A” may be implemented by only determining that “it is A”, may be implemented by only determining “it is not A”, or may be implemented by determining “whether or not it is A”.

In each embodiment described above, “any of A” means “at least one of A”.

The program executed by each device of the charging system 1 according to each embodiment described above may be provided by being recorded in a computer-readable recording medium (computer program product) such as a CD-ROM, an FD, a CD-R, or a DVD as a file in an installable format or an executable format.

Further, the program executed by each device of the charging system 1 according to each embodiment described above may be stored on a computer connected to a network such as the Internet and provided by being downloaded via the network. Further, the program executed by each device of the charging system 1 according to the embodiment described above may be provided or distributed via a network such as the Internet.

In addition, the program executed by each device of the charging system 1 according to each embodiment described above may be provided by being incorporated in the ROM or the like in advance.

According to at least one embodiment described above, a sensor abnormality can be detected without adding a redundant sensor.

According to the present disclosure, a sensor abnormality can be detected without adding a redundant sensor.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

### Supplementary Note

The following techniques are disclosed by the above description of the above embodiments.

(1)

An abnormality detection device including:
a sensor electrically connected to a power supply line to which power from an external power supply when charging an onboard battery and power from the onboard battery when discharging to an external load are bidirectionally supplied, the sensor being configured to have an output offset such that a sensor value of an applied offset voltage is output in a state where charge/discharge power is not supplied to the power supply line and output the sensor value corresponding to a current or a voltage of the charge/discharge power supplied to the power supply line; and
a control circuit configured to detect an abnormality of the sensor in a case where the sensor value in a state where the charge/discharge power is not supplied to the power supply line is different from the offset voltage.
   (2)

The abnormality detection device according to (1), in which
the sensor includes a current sensor configured to output, as the sensor value, a voltage value corresponding to a current value of a charge/discharge current flowing through the power supply line,
the sensor value corresponding to an upper limit value of an operation range related to the charge/discharge current is a first voltage value that is lower than a high-side power supply voltage of the current sensor and higher than the offset voltage,
the sensor value corresponding to a lower limit value of the operation range related to the charge/discharge current is a second voltage value that is higher than a low-side power supply voltage of the current sensor and lower than the offset voltage, and
the control circuit is configured to detect a power supply fault of the current sensor in a case where the sensor value in a state where the charge/discharge power is not supplied to the power supply line is equal to or higher than the first voltage value, and detect a ground fault of the current sensor in a case where the sensor value in a state where the charge/discharge power is not supplied to the power supply line is equal to or lower than the second voltage value.
   (3)

The abnormality detection device according to (1) or (2), in which
the current sensor includes:
   a shunt resistor electrically connected in series to the power supply line;
   an offset voltage source configured to generate the offset voltage; and
   an amplifier having an output terminal, a pair of input terminals, and a pair of power supply terminals, the output terminal being electrically connected to the control circuit, one of the pair of input terminals being electrically connected to one end of the shunt resistor via a first resistor having a first resistance value and electrically connected to the output terminal via a second resistor having a second resistance value, the other of the pair of input terminals being electrically connected to the other end of the shunt resistor via a third resistor having the first resistance value and electrically connected to the offset voltage source via a fourth resistor having the second resistance value, the pair of power supply terminals being electrically connected between the high-side power supply voltage and the low-side power supply voltage of the sensor.
      (4)

The abnormality detection device according to (2) or (3), in which
the control circuit is configured to detect a gain error of the current sensor in a case where the sensor value from the output terminal in a state where the charge/discharge power is not supplied to the power supply line is out of a predetermined range based on the offset voltage.
   (5)

The abnormality detection device according to any one of (1) to (4), in which
the sensor includes a voltage sensor configured to output, as the sensor value, a voltage value corresponding to a charge/discharge voltage applied between a voltage line and a neutral line included in the power supply line,
the sensor value corresponding to an upper limit value of an operation range related to the charge/discharge voltage is a third voltage value that is lower than a high-side power supply voltage of the voltage sensor and higher than the offset volage,
the sensor value corresponding to a lower limit value of the operation range related to the charge/discharge voltage is a fourth voltage value that is higher than a low-side power supply voltage of the voltage sensor and lower than the offset voltage, and
the control circuit is configured to detect a power supply fault of the voltage sensor in a case where the sensor value in a state where the charge/discharge power is not supplied to the power supply line is equal to or higher than the third voltage value, and detect a ground fault of the voltage sensor in a case where the sensor value in a state where the charge/discharge power is not supplied to the power supply line is equal to or lower than the fourth voltage value.
   (6)

The abnormality detection device according to any one of (1) to (5), in which
the voltage sensor includes:
   an offset voltage source configured to generate the offset voltage; and
   an amplifier having an output terminal, a pair of input terminals, and a pair of power supply terminals, the output terminal being electrically connected to the control circuit, one of the pair of input terminals being electrically connected to the voltage line via a first resistor having a first resistance value and electrically connected to the output terminal via a second resistor having a second resistance value, the other of the pair of input terminals being electrically connected to the neutral line via a third resistor having the first resistance value and electrically connected to the offset voltage source via a fourth resistor having the second resistance value, the pair of power supply terminals electrically connected between the high-side voltage and the low-side power supply voltage of the sensor.
      (7)

The abnormality detection device according to (5) or (6), in which
the control circuit is configured to detect a gain error of the voltage sensor in a case where the sensor value from the output terminal in a state where the charge/discharge power is not supplied to the power supply line is out of a predetermined range based on the offset voltage.
   (8)

An onboard charger including:
the abnormality detection device according to any one of (1) to (7); and
a power conversion circuit configured to convert alternating current power supplied from the external power supply to the power supply line into direct current power when charging the onboard battery, in which
the sensor is provided on at least one of the external power supply and the onboard battery in the power conversion circuit.
   (9)

An onboard charger including:
the abnormality detection device according to any one of (1) to (7); and
a power conversion circuit configured to convert alternating current power supplied from the external power supply to the power supply line into direct current power when charging the onboard battery, in which
the control circuit is configured to, in a case where charge power exceeds a predetermined operation range, output a control signal for stopping supply of the alternating current power to the power conversion circuit to the external power supply and detect an abnormality of the sensor based on the sensor value in a state where the charge power is not supplied to the power supply line.
   (10)

An onboard charger including:
the abnormality detection device according to any one of (1) to (7); and
a power conversion circuit configured to convert direct current power supplied from the onboard battery to the power supply line into alternating current power when discharging to the external load, in which
the sensor is provided on at least one of the external power supply and the onboard battery in the power conversion circuit.
   (11)

An onboard charger including:
the abnormality detection device according to any one of (1) to (7); and
a power conversion circuit configured to convert direct current power supplied from the onboard battery to the power supply line into alternating current power when discharging to the external load, in which
the control circuit is configured to, in a case where discharge power exceeds a predetermined operation range, stop an operation of the power conversion circuit and detect an abnormality of the sensor based on the sensor value in a state where the discharge power is not supplied to the power supply line.
   (12)

An abnormality detection method including:
by a control circuit of an abnormality detection device including a sensor electrically connected to a power supply line to which power from an external power supply when charging an onboard battery and power from an onboard battery when discharging to an external load are bidirectionally supplied, the sensor being configured to have an output offset such that a sensor value of an applied offset voltage is output in a state where charge/discharge power is not supplied to the power supply line and output the sensor value corresponding to a current or a voltage of the charge/discharge power supplied to the power supply line, detecting an abnormality of the sensor in a case where the sensor value in a state where the charge/discharge power is not supplied to the power supply line is different from the offset voltage.
   (13)

The abnormality detection method according to (12), in which
the sensor includes a current sensor configured to output, as the sensor value, a voltage value corresponding to a current value of a charge/discharge current flowing through the power supply line,
the sensor value corresponding to an upper limit value of an operation range related to the charge/discharge current is a first voltage value that is lower than a high-side power supply voltage of the current sensor and higher than the offset voltage,
the sensor value corresponding to a lower limit value of the operation range related to the charge/discharge current is a second voltage value that is higher than a low-side power supply voltage of the current sensor and lower than the offset voltage, and
a power supply fault of the current sensor is detected in a case where the sensor value in a state where the charge/discharge power is not supplied to the power supply line is equal to or higher than the first voltage value, and a ground fault of the current sensor is detected in a case where the sensor value in a state where the charge/discharge power is not supplied to the power supply line is equal to or lower than the second voltage value.
   (14)

The abnormality detection method according to (12) or (13), in which
the current sensor includes:
   a shunt resistor electrically connected in series to the power supply line;
   an offset voltage source configured to generate the offset voltage; and
   an amplifier having an output terminal, a pair of input terminals, and a pair of power supply terminals, the output terminal being electrically connected to the control circuit, one of the pair of input terminals being electrically connected to one end of the shunt resistor via a first resistor having a first resistance value and electrically connected to the output terminal via a second resistor having a second resistance value, the other of the pair of input terminals being electrically connected to the other end of the shunt resistor via a third resistor having the first resistance value and electrically connected to the offset voltage source via a fourth resistor having the second resistance value, the pair of power supply terminals being electrically connected between the high-side power supply voltage and the low-side power supply voltage of the sensor.
      (15)

The abnormality detection method according to (13) or (14), in which
a gain error of the current sensor is detected in a case where the sensor value from the output terminal in a state where the charge/discharge power is not supplied to the power supply line is out of a predetermined range based on the offset voltage.
   (16)

The abnormality detection method according to any one of (12) to (15), in which
the sensor includes a voltage sensor configured to output, as the sensor value, a voltage value corresponding to a charge/discharge voltage applied between a voltage line and a neutral line included in the power supply line,
the sensor value corresponding to an upper limit value of an operation range related to the charge/discharge voltage is a third voltage value that is lower than a high-side power supply voltage of the voltage sensor and higher than the
the sensor value corresponding to a lower limit value of the operation range related to the charge/discharge voltage is a fourth voltage value that is higher than a low-side power supply voltage of the voltage sensor and lower than the offset voltage, and
a power supply fault of the voltage sensor is detected in a case where the sensor value in a state where the charge/discharge power is not supplied to the power supply line is equal to or higher than the third voltage value, and a ground fault of the voltage sensor is detected in a case where the sensor value in a state where the charge/discharge power is not supplied to the power supply line is equal to or lower than the fourth voltage value.
   (17)

The abnormality detection method according to any one of (12) to (16), in which
the voltage sensor includes:
   an offset voltage source configured to generate the offset voltage; and
   an amplifier having an output terminal, a pair of input terminals, and a pair of power supply terminals, the output terminal being electrically connected to the control circuit, one of the pair of input terminals being electrically connected to the voltage line via a first resistor having a first resistance value and electrically connected to the output terminal via a second resistor having a second resistance value, the other of the pair of input terminals being electrically connected to the neutral line via a third resistor having the first resistance value and electrically connected to the offset voltage source via a fourth resistor having the second resistance value, the pair of power supply terminals electrically connected between the high-side voltage and the low-side power supply voltage of the sensor.
      (18)

The abnormality detection method according to (16) or (17), in which
a gain error of the voltage sensor is detected in a case where the sensor value from the output terminal in a state where the charge/discharge power is not supplied to the power supply line is out of a predetermined range based on the offset voltage.
   (19)

The abnormality detection method according to any one of (12) to (18), in which
the abnormality detection method is executed by the control circuit in an onboard charger including the abnormality detection device and a power conversion circuit configured to convert alternating current power supplied from the external power supply to the power supply line into direct current power when charging the onboard battery, and
the sensor is provided on at least one of the external power supply and the onboard battery in the power conversion circuit.
   (20)

The abnormality detection method according to any one of (12) to (19), in which
in an onboard charger including the abnormality detection device and a power conversion circuit configured to convert alternating current power supplied from the external power supply to the power supply line into direct current power when charging the onboard battery, by the control circuit,
a control signal for stopping supply of the alternating current power to the power conversion circuit is output to the external power supply in a case where charge power exceeds a predetermined operation range, and an abnormality of the sensor is detected based on the sensor value in a state where the charge power is not supplied to the power supply line.
   (21)

The abnormality detection method according to any one of (12) to (20), in which
the abnormality detection method is executed by the control circuit in an onboard charger including the abnormality detection device and a power conversion circuit configured to convert direct current power supplied from the onboard battery to the power supply line into alternating current power when discharging to the external load, and
the sensor is provided on at least one of the external power supply and the onboard battery in the power conversion circuit.
   (22)

The abnormality detection method according to any one of (12) to (21), in which
in an onboard charger including the abnormality detection device and a power conversion circuit configured to convert direct current power supplied from the onboard battery to the power supply line into alternating current power when discharging to the external load, by the control circuit,
an operation of the power conversion circuit is stopped in a case where discharge power exceeds a predetermined operation range, and an abnormality of the sensor is detected based on the sensor value in a state where the discharge power is not supplied to the power supply line.
   (23)

A vehicle including:
the onboard charger according to any one of (8) to (11); and
the onboard battery.
   (24)

A program for causing a computer to execute the abnormality detection method according to any one of (12) to (22).

(25)

A storage medium (computer program product) on which the program to be executed by a computer, according to (24), is recorded.

What is claimed is:

1. An abnormality detection device comprising:
a sensor electrically connected to a power supply line to which power from an external power supply when charging an onboard battery and power from the onboard battery when discharging to an external load are bidirectionally supplied, the sensor being configured to have an output offset such that a sensor value of an applied offset voltage is output in a state where charge/discharge power is not supplied to the power supply line and output the sensor value corresponding to a current or a voltage of the charge/discharge power supplied to the power supply line; and
a control circuit configured to detect an abnormality of the sensor in a case where the sensor value in a state where the charge/discharge power is not supplied to the power supply line is different from the offset voltage.

2. The abnormality detection device according to claim 1, wherein
the sensor includes a current sensor configured to output, as the sensor value, a voltage value corresponding to a current value of a charge/discharge current flowing through the power supply line,
the sensor value corresponding to an upper limit value of an operation range related to the charge/discharge current is a first voltage value that is lower than a high-side power supply voltage of the current sensor and higher than the offset voltage,
the sensor value corresponding to a lower limit value of the operation range related to the charge/discharge current is a second voltage value that is higher than a low-side power supply voltage of the current sensor and lower than the offset voltage, and
the control circuit is configured to detect a power supply fault of the current sensor in a case where the sensor value in a state where the charge/discharge power is not supplied to the power supply line is equal to or higher than the first voltage value, and detect a ground fault of the current sensor in a case where the sensor value in a state where the charge/discharge power is not supplied to the power supply line is equal to or lower than the second voltage value.

3. The abnormality detection device according to claim 2, wherein
the current sensor includes:
a shunt resistor electrically connected in series to the power supply line;
an offset voltage source configured to generate the offset voltage; and
an amplifier having an output terminal, a pair of input terminals, and a pair of power supply terminals, the output terminal being electrically connected to the control circuit, one of the pair of input terminals being electrically connected to one end of the shunt resistor via a first resistor having a first resistance value and electrically connected to the output terminal via a second resistor having a second resistance value, the other of the pair of input terminals being electrically connected to the other end of the shunt resistor via a third resistor having the first resistance value and electrically connected to the offset voltage source via a fourth resistor having the second resistance value, the pair of power supply terminals being electrically connected between the high-side power supply voltage and the low-side power supply voltage of the sensor.

4. The abnormality detection device according to claim 3, wherein
the control circuit is configured to detect a gain error of the current sensor in a case where the sensor value from the output terminal in a state where the charge/discharge power is not supplied to the power supply line is out of a predetermined range based on the offset voltage.

5. The abnormality detection device according to claim 1, wherein
the sensor includes a voltage sensor configured to output, as the sensor value, a voltage value corresponding to a charge/discharge voltage applied between a voltage line and a neutral line included in the power supply line,
the sensor value corresponding to an upper limit value of an operation range related to the charge/discharge voltage is a third voltage value that is lower than a high-side power supply voltage of the voltage sensor and higher than the offset voltage,
the sensor value corresponding to a lower limit value of the operation range related to the charge/discharge voltage is a fourth voltage value that is higher than a low-side power supply voltage of the voltage sensor and lower than the offset voltage, and
the control circuit is configured to detect a power supply fault of the voltage sensor in a case where the sensor value in a state where the charge/discharge power is not supplied to the power supply line is equal to or higher than the third voltage value, and detect a ground fault of the voltage sensor in a case where the sensor value in a state where the charge/discharge power is not supplied to the power supply line is equal to or lower than the fourth voltage value.

6. The abnormality detection device according to claim 5, wherein
the voltage sensor includes:
an offset voltage source configured to generate the offset voltage; and
an amplifier having an output terminal, a pair of input terminals, and a pair of power supply terminals, the output terminal being electrically connected to the control circuit, one of the pair of input terminals being electrically connected to the voltage line via a first resistor having a first resistance value and electrically connected to the output terminal via a second resistor having a second resistance value, the other of the pair of input terminals being electrically connected to the neutral line via a third resistor having the first resistance value and electrically connected to the offset voltage source via a fourth resistor having the second resistance value, the pair of power supply terminals electrically connected between the high-side voltage and the low-side power supply voltage of the sensor.

7. The abnormality detection device according to claim 6, wherein
the control circuit is configured to detect a gain error of the voltage sensor in a case where the sensor value from the output terminal in a state where the charge/discharge power is not supplied to the power supply line is out of a predetermined range based on the offset voltage.

8. An onboard charger comprising:
the abnormality detection device according to claim 1; and
a power conversion circuit configured to convert alternating current power supplied from the external power supply to the power supply line into direct current power when charging the onboard battery, wherein
the sensor is provided on at least one of the external power supply and the onboard battery in the power conversion circuit.

9. An onboard charger comprising:
the abnormality detection device according to claim 1; and
a power conversion circuit configured to convert alternating current power supplied from the external power supply to the power supply line into direct current power when charging the onboard battery, wherein
the control circuit is configured to, in a case where charge power exceeds a predetermined operation range, output a control signal for stopping supply of the alternating current power to the power conversion circuit to the external power supply and detect an abnormality of the sensor based on the sensor value in a state where the charge power is not supplied to the power supply line.

10. An onboard charger comprising:
the abnormality detection device according to claim 1; and
a power conversion circuit configured to convert direct current power supplied from the onboard battery to the power supply line into alternating current power when discharging to the external load, wherein
the sensor is provided on at least one of the external power supply and the onboard battery in the power conversion circuit.

11. An onboard charger comprising:
the abnormality detection device according to claim 1; and
a power conversion circuit configured to convert direct current power supplied from the onboard battery to the power supply line into alternating current power when discharging to the external load, wherein
the control circuit is configured to, in a case where discharge power exceeds a predetermined operation range, stop an operation of the power conversion circuit and detect an abnormality of the sensor based on the sensor value in a state where the discharge power is not supplied to the power supply line.

12. An abnormality detection method comprising:
by a control circuit of an abnormality detection device including a sensor electrically connected to a power supply line to which power from an external power supply when charging an onboard battery and power from an onboard battery when discharging to an external load are bidirectionally supplied, the sensor being configured to have an output offset such that a sensor value of an applied offset voltage is output in a state where charge/discharge power is not supplied to the power supply line and output the sensor value corresponding to a current or a voltage of the charge/discharge power supplied to the power supply line,
detecting an abnormality of the sensor in a case where the sensor value in a state where the charge/discharge power is not supplied to the power supply line is different from the offset voltage.

13. The abnormality detection method according to claim 12, wherein
the sensor includes a current sensor configured to output, as the sensor value, a voltage value corresponding to a current value of a charge/discharge current flowing through the power supply line,
the sensor value corresponding to an upper limit value of an operation range related to the charge/discharge current is a first voltage value that is lower than a high-side power supply voltage of the current sensor and higher than the offset voltage,
the sensor value corresponding to a lower limit value of the operation range related to the charge/discharge current is a second voltage value that is higher than a low-side power supply voltage of the current sensor and lower than the offset voltage, and
a power supply fault of the current sensor is detected in a case where the sensor value in a state where the charge/discharge power is not supplied to the power supply line is equal to or higher than the first voltage value, and a ground fault of the current sensor is detected in a case where the sensor value in a state where the charge/discharge power is not supplied to the power supply line is equal to or lower than the second voltage value.

14. The abnormality detection method according to claim 13, wherein
the current sensor includes:
a shunt resistor electrically connected in series to the power supply line;
an offset voltage source configured to generate the offset voltage; and
an amplifier having an output terminal, a pair of input terminals, and a pair of power supply terminals, the output terminal being electrically connected to the control circuit, one of the pair of input terminals being electrically connected to one end of the shunt resistor via a first resistor having a first resistance value and electrically connected to the output terminal via a second resistor having a second resistance value, the other of the pair of input terminals being electrically connected to the other end of the shunt resistor via a third resistor having the first resistance value and electrically connected to the offset voltage source via a fourth resistor having the second resistance value, the pair of power supply terminals being electrically connected between the high-side power supply voltage and the low-side power supply voltage of the sensor.

15. The abnormality detection method according to claim 14, wherein
a gain error of the current sensor is detected in a case where the sensor value from the output terminal in a state where the charge/discharge power is not supplied to the power supply line is out of a predetermined range based on the offset voltage.

16. The abnormality detection method according to claim 12, wherein
the sensor includes a voltage sensor configured to output, as the sensor value, a voltage value corresponding to a charge/discharge voltage applied between a voltage line and a neutral line included in the power supply line,
the sensor value corresponding to an upper limit value of an operation range related to the charge/discharge voltage is a third voltage value that is lower than a high-side power supply voltage of the voltage sensor and higher than the offset voltage,
the sensor value corresponding to a lower limit value of the operation range related to the charge/discharge voltage is a fourth voltage value that is higher than a low-side power supply voltage of the voltage sensor and lower than the offset voltage, and
a power supply fault of the voltage sensor is detected in a case where the sensor value in a state where the charge/discharge power is not supplied to the power supply line is equal to or higher than the third voltage value, and a ground fault of the voltage sensor is detected in a case where the sensor value in a state where the charge/discharge power is not supplied to the power supply line is equal to or lower than the fourth voltage value.

17. The abnormality detection method according to claim 16, wherein
the voltage sensor includes:
an offset voltage source configured to generate the offset voltage; and
an amplifier having an output terminal, a pair of input terminals, and a pair of power supply terminals, the output terminal being electrically connected to the control circuit, one of the pair of input terminals being electrically connected to the voltage line via a first resistor having a first resistance value and electrically connected to the output terminal via a second resistor having a second resistance value, the other of the pair of input terminals being electrically connected to the neutral line via a third resistor having the first resistance value and electrically connected to the offset voltage source via a fourth resistor having the second resistance value, the pair of power supply terminals electrically connected between the high-side voltage and the low-side power supply voltage of the sensor.

18. The abnormality detection method according to claim 17, wherein
a gain error of the voltage sensor is detected in a case where the sensor value from the output terminal in a state where the charge/discharge power is not supplied to the power supply line is out of a predetermined range based on the offset voltage.

19. The abnormality detection method according to claim 12, wherein
in an onboard charger including the abnormality detection device and a power conversion circuit configured to convert alternating current power supplied from the external power supply to the power supply line into direct current power when charging the onboard battery, by the control circuit,
a control signal for stopping supply of the alternating current power to the power conversion circuit is output to the external power supply in a case where charge power exceeds a predetermined operation range, and an abnormality of the sensor is detected based on the sensor value in a state where the charge power is not supplied to the power supply line.

20. The abnormality detection method according to claim 12, wherein
in an onboard charger including the abnormality detection device and a power conversion circuit configured to convert direct current power supplied from the onboard battery to the power supply line into alternating current power when discharging to the external load, by the control circuit,
an operation of the power conversion circuit is stopped in a case where discharge power exceeds a predetermined operation range, and an abnormality of the sensor is detected based on the sensor value in a state where the discharge power is not supplied to the power supply line.
